(19) United States
(12) Patent Application Publication
(10) Pub. No.: US 2026/0018409 A1
(43) Pub. Date: Jan. 15, 2026

(54) POST TREATMENT PROCESSES

(71) Applicant: Applied Materials, Inc., Santa Clara, CA (US)

(72) Inventors: Rui LU, Santa Clara, CA (US); Kent Qiujing ZHAO, San Francisco, CA (US); Bhaskar SOMAN, Santa Clara, CA (US); Bo XIE, San Jose, CA (US); Chi-I LANG, Cupertino, CA (US); Li-Qun XIA, Santa Clara, CA (US); Shankar VENKATARAMAN, San Jose, CA (US)

(21) Appl. No.: 18/770,153

(22) Filed: Jul. 11, 2024

(51) Int. Cl. H01L 21/02

(52) U.S. Cl. CPC H01L 21/02274; H01L 21/02164; H01L 21/02211; H01L 21/02216

(57) ABSTRACT

The present disclosure generally provides methods. The methods include exposing a substrate in a processing chamber to a deposition precursor to form a first film. The first film having a first dielectric constant, a first leakage current, a first breakdown voltage, and a first hardness. The first film is exposed to a reactive precursor to form a second film. The second film having a second dielectric constant, a second leakage current, a second breakdown voltage, and a second hardness, wherein the reactive precursor comprises an oxygenated precursor. The second film is exposed to a UV light source to form a third film. The third film having a third dielectric constant, a third leakage current, a third breakdown voltage, and a third hardness.

### FIELD

Embodiments described herein generally relate to processes for processing low-k dielectric films. More specifically, embodiments described herein relate to processes for controlling current leakage while maintaining the dielectric constant and hardness.

### BACKGROUND

The dielectric constant (k) of dielectric films in semiconductor fabrication is continually decreasing as device scaling continues. Minimizing integration damage on low dielectric constant (low-k) films is beneficial to be able to continue decreasing feature sizes. Unfortunately, damage incurred to low-k films through various processes can cause increases in dielectric constant and leakage, both of which can result in decreased device performance (e.g., potential failure of an integrated circuit).

Efforts have been directed towards developing processes designed to recover properties lost due to accrued damage to the low-k film. However, while the resulting properties of low-k films subjected to such processes have resulted in reduced dielectric constants, the leakage properties of the low-k films also reduced, thereby reducing device performance.

Thus, there is a need for improved processes for forming low-k films.

### SUMMARY

The present disclosure generally provides methods. The methods include exposing a substrate in a processing chamber to a deposition precursor to form a first film. The first film having a first dielectric constant, a first leakage current, a first breakdown voltage, and a first hardness. The first film is exposed to a reactive precursor to form a second film. The second film having a second dielectric constant, a second leakage current, a second breakdown voltage, and a second hardness, wherein the reactive precursor comprises an oxygenated precursor. The second film is exposed to a UV light source to form a third film. The third film having a third dielectric constant, a third leakage current, a third breakdown voltage, and a third hardness.

The present disclosure also generally provides methods. The methods include exposing a substrate in a processing chamber to a deposition precursor. The deposition precursor having a structure of Formula (I) to form a first film on the substrate. Formula (I) is represented by

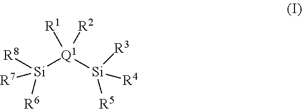

wherein Q¹ is a carbon atom or an oxygen atom; and each of R¹, R², R³, R⁴, R⁵, R⁶, R⁷, and R⁸ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide. The first film is exposed to a reactive precursor comprising diatomic oxygen or ozone to form an second film. The second film is exposed to a UV light source to form a third film.

The present disclosure also generally provides methods. The methods include exposing a substrate in a processing chamber to a deposition precursor having a structure of Formula (I) to form a first film on the substrate. The first film has a first dielectric constant, a first leakage current, a first breakdown voltage, and a first hardness. Formula (I) is represented by

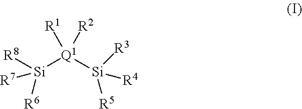

wherein Q¹ is a carbon atom or an oxygen atom; and each of R¹, R², R³, R⁴, R⁵, R⁶, R⁷, and R⁸ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide. The first film is exposed to a reactive precursor comprising diatomic oxygen or ozone to form an second film. Exposing the first film includes introducing the reactive precursor to the processing chamber at a flow rate of about 500 standard cubic centimeters per minute (sccm) to about 2,000 sccm. A carrier gas is introduced into the processing chamber at a flow rate of about 10,000 sccm to about 17,000 sccm. A pressure is maintained at about 10 Torr to about 15 Torr and a temperature of about 5° C. to about 400° C. The second film is exposed to a UV light source to form a third film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of scope, for the disclosure may admit to other equally effective embodiments.

FIG. 1 is a schematic cross-sectional view of a first process chamber, according to at least an embodiment of the present disclosure

FIG. 2 is a schematic cross-sectional view of a second process chamber, according to at least an embodiment of the present disclosure.

FIG. 3 is a schematic block diagram of a method of substrate processing, according to at least an embodiment of the present disclosure.

FIG. 4 is a diagrammatic representation of a bonding comparison between a UV treated substrate and an second film, according to at least an embodiment of the present disclosure.

FIG. 5 is a diagrammatic representation of a leakage current comparison between a UV treated substrate and an second film, according to at least an embodiment of the present disclosure.

FIG. 6 is a diagrammatic representation of a dielectric constant and hardness of a film, according to at least an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure provides methods to control dielectric constant properties, leakage properties, breakdown voltages, and hardness values of low-k films that were damaged during substrate processing procedures. Processes disclosed herein generally include a series of operations including exposing the substrate to one or more reactive precursors, e.g., an oxygenated precursor, in the presence of heat and/or plasma followed by exposure to a UV light source to allow for controllability of one or more of dielectric constant properties, leakage properties, breakdown voltages, and hardness values. Processes disclosed herein can reduce elevated k values of damaged low-k films, and also reduce leakage properties of such films, thereby enhancing device performance. Additionally, the processes of the present disclosure provide a balance between the reduction of low-k values, reduction of leakage properties, and increase of breakdown voltage properties, without sacrificing hardness values in low-k films, such that the resulting films have enhanced device performance compared to conventional low-k films.

Before describing several exemplary embodiments of the disclosure, it is to be understood that the disclosure is not limited to the details of construction or process steps set forth in the following description. The disclosure is capable of other embodiments and of being practiced or being carried out in various ways.

Many of the details, dimensions, angles and other features shown in the Figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

A “substrate,” “substrate surface,” or the like, as used herein, refers to any substrate or material surface formed on a substrate upon which processing is performed. For example, a substrate surface on which processing can be performed include, but are not limited to, materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what materials are to be deposited, as well as the particular chemistry used.

As used in this specification and the appended claims, the terms “reactive compound,” “reactive gas,” “reactive species,” “precursor,” “process gas,” and the like are used interchangeably to mean a substance with a species capable of reacting with the substrate surface or material on the substrate surface in a surface reaction (e.g., chemisorption, oxidation, reduction). For example, a first “reactive gas” may simply adsorb onto the surface of a substrate and be available for further chemical reaction with a second reactive gas.

As used in this specification and the appended claims, the terms “precursor,” “reactant,” “reactive gas” and the like are used interchangeably to refer to any gaseous species that can react with the substrate surface.

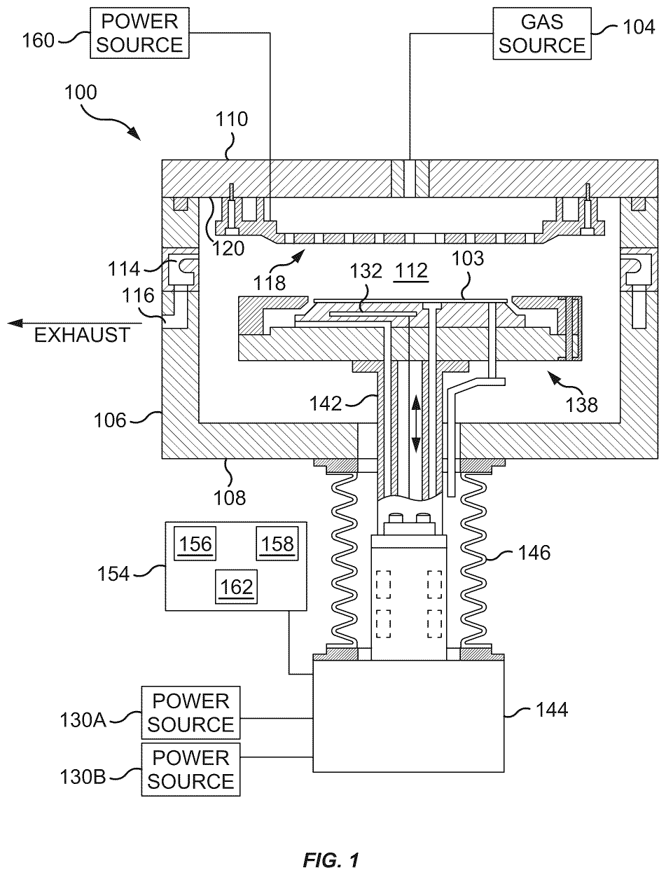

FIG. 1 is a schematic cross-sectional view of a process chamber 100, such as a CVD process chamber, that may be used for depositing a silicon based layer according to the embodiments described herein. A process chamber 100 is available from Applied Materials, Inc. located in Santa Clara, Calif., and a brief description thereof follows. Processing chambers that may be adapted to perform the carbon layer deposition methods described herein the PRECISION® chemical vapor deposition chamber, available from Applied Materials, Inc. located in Santa Clara, Calif. It is to be understood that the chamber described below is an exemplary embodiment and other chambers, including chambers from other manufacturers, may be used with or modified to match embodiments described herein without diverging from the inventive characteristics described herein.

The process chamber 100 may be part of a processing system (not shown) that includes multiple processing chambers connected to a central transfer chamber (not shown) and serviced by a robot (not shown). The process chamber 100 includes walls 106, a bottom 108, and a lid 110 that define a process volume 112. The walls 106 and bottom 108 can be fabricated from a unitary block of aluminum. The process chamber 100 may also include a pumping ring 114 that fluidly couples the process volume 112 to an exhaust port 116 as well as other pumping components (not shown).

A substrate support assembly 138, which may be heated, may be centrally disposed within the process chamber 100. The substrate support assembly 138 supports a substrate 103 during a deposition process. The substrate support assembly 138 generally is fabricated from aluminum, ceramic or a combination of aluminum and ceramic, and includes at least one bias electrode 132.

A vacuum port may be used to apply a vacuum between the substrate 103 and the substrate support assembly 138 to secure the substrate 103 to the substrate support assembly 138 during the deposition process. The bias electrode 132, may be, for example, the bias electrode 132 disposed in the substrate support assembly 138, and coupled to a bias power source 130A and 130B, to bias the substrate support assembly 138 and substrate 103 positioned thereon to a predetermined bias power level while processing.

The bias power source 130A and 130B can be independently configured to deliver power to the substrate 103 and the substrate support assembly 138 at a variety of frequencies, such as a frequency between about 1 MHz and about 60 MHz. In one embodiment, the bias power source 130A may be configured to deliver power to the substrate 103 at a frequency of about 2 MHz and the bias power source 130B may be configured to deliver power to the substrate 103 at a frequency of about 13.56 MHz. In another embodiment, the bias power source 130A may be configured to deliver power to the substrate support at a frequency of 2 MHZ, the bias power source 130B may be configured to deliver power to the substrate 103 at a frequency of 13.56 MHz and a third power source (not shown) is configured to deliver power to the substrate 103 at a frequency of about 60 MHz. Various permutations of the frequencies described here can be employed without diverging from the embodiments described herein.

Generally, the substrate support assembly 138 is coupled to a stem 142. The stem 142 provides a conduit for electrical leads, vacuum and gas supply lines between the substrate support assembly 138 and other components of the process chamber 100. Additionally, the stem 142 couples the substrate support assembly 138 to a lift system 144 that moves the substrate support assembly 138 between an elevated position (as shown in FIG. 1) and a lowered position (not shown) to facilitate robotic transfer. Bellows 146 provide a vacuum seal between the process volume 112 and the atmosphere outside the process chamber 100 while facilitating the movement of the substrate support assembly 138.

The showerhead 118 may generally be coupled to an interior side 120 of the lid 110. Gases (e.g., process and other gases such as an oxygen precursor, e.g., diatomic oxygen and/or ozone) that enter the process chamber 100 from a gas source 104 pass through the showerhead 118 and into the process chamber 100. The showerhead 118 may be configured to provide a uniform flow of gases to the process chamber 100. Uniform gas flow is desirable to promote uniform layer formation on the substrate 103. A plasma power source 160 may be coupled to the showerhead 118 to energize the gases through the showerhead 118 towards substrate 103 disposed on the substrate support assembly 138. The plasma power source 160 may provide RF power. Further, the plasma power source 160 can be configured to deliver power to the showerhead 118 at a variety of frequencies, such as a frequency between about 100 kHz and about 40 MHz. In one embodiment, the plasma power source 160 is configured to deliver power to the showerhead 118 at a frequency of 13.56 MHz.

The function of the process chamber 100 can be controlled by a computing device 154. The computing device 154 may be one of any form of general purpose computer that can be used in an industrial setting for controlling various chambers and sub-processors. The computing device 154 includes a computer processor 156. The computing device 154 includes memory 158. The memory 158 may include any suitable memory, such as random access memory, read only memory, flash memory, hard disk, or any other form of digital storage, local or remote. The computing device 154 may include various support circuits 162, which may be coupled to the computer processor 156 for supporting the computer processor 156 in a conventional manner. Software routines, as required, may be stored in the memory or executed by a second computing device (not shown) that is remotely located.

The computing device 154 may further include one or more computer readable media (not shown). Computer readable media generally includes any device, located either locally or remotely, which is capable of storing information that is retrievable by a computing device. Examples of computer readable media useable with embodiments of the present embodiments include solid state memory, floppy disks, internal or external hard drives, and optical memory (CDs, DVDs, BR-D, etc). In one embodiment, the memory 158 may be the computer readable media. Software routines may be stored on the computer readable media to be executed by the computing device.

The software routines, when executed, transform the general purpose computer into a specific process computer that controls the chamber operation so that a chamber process is performed. Alternatively, the software routines may be performed in hardware as an application specific integrated circuit or other type of hardware implementation, or a combination of software and hardware.

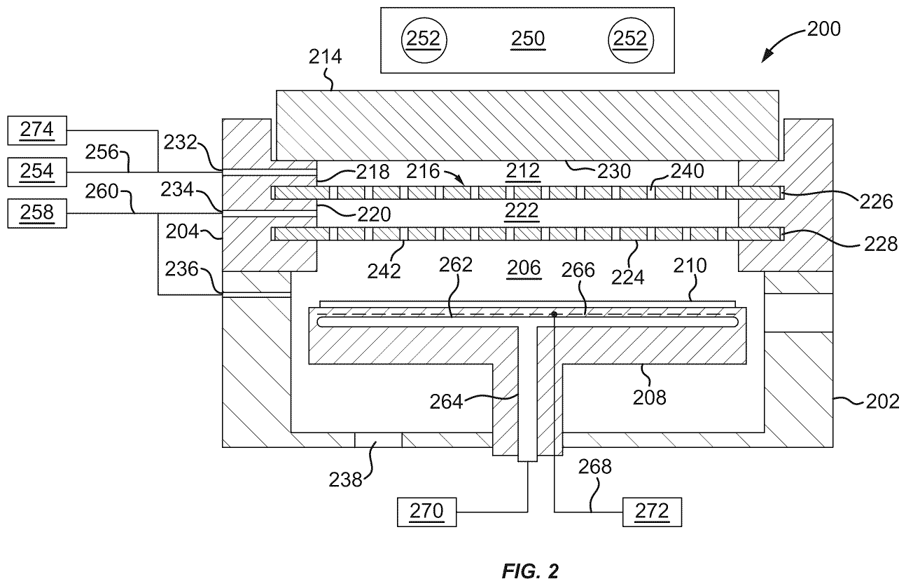

FIG. 2 is a schematic cross-sectional view of a process chamber 200, according to at least an embodiment of the present disclosure. The process chamber 200 may be a vapor deposition chamber that includes UV radiation for assisting a silylation reaction. The process chamber 200 may include a chamber body 202 and a chamber lid 204 disposed over the chamber body 202. The chamber body 202 and the chamber lid 204 may form an inner volume 206. A substrate support assembly 108 may be disposed in the inner volume 206. The substrate support assembly 208 may receive and support a substrate 210 thereon for processing.

A first UV transparent gas distribution showerhead 216 may be disposed in the inner volume 206 within a central opening 212 of the chamber lid 204 by an upper clamping member 218 and a lower clamping member 220. The UV transparent distribution showerhead 216 may be positioned facing the substrate support assembly 208 to distribute one or more processing gases across a distribution volume 222 which is below the first UV transparent gas distribution showerhead 216. A second UV transparent showerhead 224 may be disposed in the inner volume 206 within the central opening 212 of the chamber lid 204 below the first UV transparent gas distribution showerhead 216. Each of the UV transparent gas distribution showerheads 216, 224 may be disposed in a recess formed in the chamber lid 204. A first recess 226 may be an annular recess around an internal surface of the chamber lid 204, and the first UV transparent gas distribution showerhead 216 fits into the first recess 226. Likewise, a second recess 228 may receive the second UV transparent gas distribution showerhead 224.

A UV transparent window 214 may be disposed above the first UV transparent gas distribution showerhead 216. The UV transparent window 214 may be positioned above the first UV transparent gas distribution showerhead 216 forming a gas volume 230 between the UV transparent window 214 and the first UV transparent gas distribution showerhead 216. The UV transparent window 214 may be secured to the chamber lid 204 by any means, such as clamps, screws, bolts, etc.

The UV transparent window 214 and the first and second UV transparent gas distribution showerheads 216, 224 may be at least partially transparent to thermal or radiant energy within the UV wavelengths. The UV transparent window 214 may be quartz or another UV transparent material, such as sapphire, CaF₂, MgF₂, AlON, a silicon oxide material, a silicon oxynitride material, or another transparent material.

A UV source 250 may be disposed above the UV transparent window 214. The UV source 250 may be configured to generate UV energy and project the UV energy towards the substrate support assembly 208 through the UV transparent window 214, the first UV transparent gas distribution showerhead 216, and the second UV transparent gas distribution showerhead 224, thereby exposing the substrate 210 on the substrate support assembly 208 to UV light. A cover (not shown) may be disposed above the UV source 250. In one or more embodiments, the cover may be shaped to assist the projection of the UV energy from the UV source 250 towards the substrate support.

In one or more embodiments, the UV source 250 may include one or more UV lights 252 to generate UV radiation. The UV lights 252 may be lamps, LED emitters, or other UV emitters capable of emitting a wavelength of light of about 100 nm to about 400 nm. For example, the UV lights 252 may be argon lamps discharging radiation at 126 nm, krypton lamps discharging at 146 nm, xenon lamps discharging at 172 nm, krypton chloride lamps discharging at 222 nm, xenon chloride lamps discharging at 308 nm, mercury lamps discharging at 254 nm or 365 nm, metal vapor lamps such as zinc discharging at 214 nm, or rare earth near-UV lamps such as europium-doped strontium borate or fluoroborate lamps discharging at 368-371 nm.

The process chamber 200 may include flow channels 232, 234, 236 configured to supply one or more processing gases across the substrate support assembly 208 to process a substrate 210 disposed thereon. A first flow channel 232 provides a flow pathway for gas to enter the gas volume 230 and to be exposed to UV radiation from the UV source 120. The gas from the gas volume 230 may flow through the first UV transparent gas distribution showerhead 216 into the distribution volume 222. A second flow channel 234 may provide a flow pathway for precursor compounds and gases to enter the distribution volume 222 directly without passing through the first UV transparent gas distribution showerhead 216 to mix with the gas that was previously exposed to UV radiation in the gas volume 230. The mixed gases in the distribution volume 222 may be further exposed to UV radiation through the first UV transparent gas distribution showerhead 216 before flowing through the second UV transparent gas distribution showerhead 224 into a space proximate the substrate support assembly 208. The gas proximate the substrate support assembly 208, and a substrate disposed on the substrate support assembly 208, is further exposed to the UV radiation through the second UV transparent gas distribution showerhead 224. Purge gases may be provided through an opening 238 in the bottom of the process chamber 200 such that the purge gas flow around the substrate support assembly 208, preventing intrusion of processing gases into the space under the substrate support assembly 208. One or more gases may be exhausted through the opening 238.

The first UV transparent gas distribution showerhead 216 may include a plurality of holes 240 that allow processing gas to flow from the gas volume 230 to the distribution volume 222. The second UV transparent gas distribution showerhead 224 may also include a plurality of holes 242 that allow processing gas to flow from the distribution volume 222 into the processing space proximate the substrate support assembly 208. The holes 240, 242 in the first and second UV transparent gas distribution showerheads 216, 224 may be evenly distributed or irregularly spaced.

A purge gas or carrier gas source 254 may be coupled to the first flow channel 232 through a conduit 256. Purge gas from the purge gas source 254 may be provided through the first flow channel 232 during substrate processing to prevent intrusion of process gases into the gas volume 230. A cleaning gas source 274 may also be coupled to the first flow channel 232 through the conduit 256 to provide cleaning of the conduit 256, the first flow channel 232, the gas volume 230, and the rest of the chamber 202 when not processing substrates.

A process gas or precursor compound source 258 may be coupled to the second flow channel 234 through a conduit 260 to provide a mixture, as described above, to the chamber body 202. The process gas source 258 may also be coupled to a third flow channel 236. Appropriate valves may allow selection of one or both of the flow channels 234, 236 for flowing the process gas mixture into the chamber body 202.

Substrate temperature may be controlled by providing heating and cooling features in the substrate support assembly 208. A coolant conduit 264 may be coupled to a coolant source 270 to provide a coolant to a cooling plenum 262 disposed in the substrate support assembly 208. One example of a coolant that may be used is a mixture of 50% ethylene glycol in water, by volume. The coolant flow is controlled to maintain temperature of the substrate at or below a desired level to promote deposition of UV-activated oligomers or fragments on the substrate. A heating element 266 may also be provided in the substrate support assembly 208. The heating element 266 may be a resistive heater, and may be coupled to a heating source 272, such as a power supply, by a conduit 268. The heating element 266 may be used to heat the substrate during the hardening process described above.

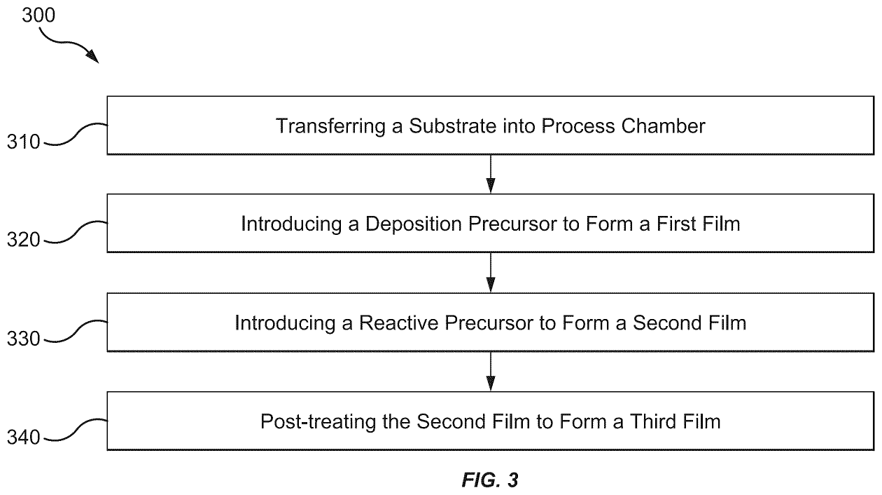

FIG. 3 is a schematic block diagram of a method 300 of substrate processing, according to one or more embodiments. At operation 310, a substrate may be introduced to a process chamber (e.g., process chamber 100) and positioned on a substrate support capable of performing CVD and/or PECVD. At operation 320, a low-k film may be deposited onto a substrate from one or more precursors introduced into the processing chamber via vapor deposition.

At operation 320, one or more deposition precursors can be introduced to the processing chamber, (e.g., process chamber 100) to deposit a low-k film on the substrate. The deposition process may include one or more of chemical vapor deposition (CVD), atomic layer deposition (ALD), PECVD, or a combination thereof. An inert carrier gas, such as a noble gas (e.g., argon or helium) may be introduced to the processing chamber with the one or more deposition precursors. The one or more deposition precursors are reacted in the presence of RF power to deposit a low-k film on the substrate in the processing chamber.

In some examples, the one or more deposition precursors includes a silicon-containing component, in which a silicon atom is bonded to at least one of a carbon atom and/or an oxygen atom. In at least one embodiment, the silicon containing component may include any one or more silicon based compound, such as trimethylsilane, triethoxysilane, methyldiethoxysilane, dimethylethoxysilane, dimethylmethoxysilane, methyldimethoxysilane, dimethyldisiloxane, tetramethyldisiloxane, 1,3-bis(silanomethylene)disiloxane, bis(1-methyldisiloxanyl)methane, bis(1-methyldisiloxanyl)propane, and combinations thereof.

Other deposition precursors may include, for example, dimethyldimethoxysilane (DMDMOS), methyldiethoxysilane (MDEOS), trimethylsilane (TMS), triethoxysilane, dimethylethoxysilane, dimethyldisiloxane, tetramethyldisiloxane, hexamethyldisiloxane (HMDS), 1,3-bis(silanomethylene)disiloxane, bis(1-methyldisiloxanyl)methane, bis(1-methyldisiloxanyl)propane, hexamethoxydisiloxane (HMDOS), dimethoxymethylvinylsilane (DMMVS), and combinations thereof. In some embodiments, the one or more deposition precursors may include one or more cyclic compounds, such as tetramethylcyclotetrasiloxane (TMCTS), octamethylcyclotetrasiloxane (OMCTS), pentamethylcyclopentasiloxane, hexamethylcyclotrisiloxane, and combinations thereof.

Additionally or alternatively, the one or more deposition precursors may include one or more compounds which can be represented by Formula (I):

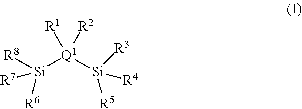

wherein Q¹ is either a carbon atom or an oxygen atom, and each of R¹, R², R³, R⁴, R⁵, R⁶, R⁷, and R⁸ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide. In at least one embodiment, at least one of R¹, R², R³, R⁴, R⁵, R⁶, R⁷, and R⁸ is a dimethylamine group, wherein the linkage to the compound of Formula (I) occurs through the nitrogen atom

The one or more organosilicon compounds may include one or more compounds which can be represented by Formula (II):

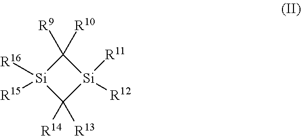

wherein Q² is either a carbon atom or a silicon atom, and each of R⁹, R¹⁰, R¹¹, R¹², R¹³, R¹⁴, R¹⁵, and R¹⁶ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide. In at least one embodiment, at least one of R⁹, R¹⁰, R¹¹, R¹², R¹³, R¹⁴, R¹⁵, and R¹⁶ is a dimethylamine group, wherein the linkage to the compound of Formula (II) occurs through the nitrogen atom.

Additionally or alternatively, the one or more deposition precursors may include one or more of 1,1-Bis(dimethylamino)-3,3-bis(dimethylamino)siletane, 1,3-Bis(dimethylamino)-1,3-divinyl-1,3-disiletane, 1,3-Bis(dimethylamino)-1,3-dimethyl-1,3-disiletane, 1,1,3,3-Tetrakis(dimethylamino)-1,3-disiletane, 1,3-Bis(dimethylamino)-1,3-divinyl-1,3-disiletane, Bis(trisdimethylamino)silyl methane, and the like.

Additionally or alternatively, the one or more deposition precursors may include one of octamethylcyclotetrasiloxane, 2,4,6,8-tetramethyl-2,4,6,8-tetravinylcyclotetrasiloxane, 2,4,6,8-tetramethylcyclotetrasiloxane, dimethyldimethoxysilane, ethoxydimethylsilane, isobutylmethyldimethoxysilane, vinylmethyldimethoxysilane, 1,1,3,3-tetramethyl-1,3-dimethoxydisiloxane, 1,3-dimethyl-1,1,3,3-tetramethoxydisiloxane, methoxy(dimethyl)silylmethane, methyl(dimethoxy)silylmethane, bis(trimethylsilyl)methane, 1,3-diethoxy-1,3-dimethyl-1,3-disilacyclobutane, and 1,3-dimethyl-1,3-diphenyl-1,3-disilacyclobutane.

Without being bound by theory, a silicon-carbon-silicon precursor can allow for a film having a reduced k-value, an increased breakdown voltage, a reduced leakage property, and an increased hardness compared to conventional deposition precursors. In some embodiments, the deposition precursors can include one or more of a silicon-oxygen-silicon precursor, e.g., 1,1,3,3-tetramethyl-1,3-dimethoxydisiloxane or 1,3-dimethyl-1,1,3,3-tetramethoxydisiloxane.

In some embodiments, which may be combined with other embodiments, the deposition precursor may be introduced to the process chamber 100 while maintaining the temperature of the substrate and/or process chamber at about 100° C. to about 450° C., e.g., about 100° C. to about 400° C., about 150° C. to about 350° C., about 200° C. to about 350° C., or about 250° C. to about 350° C. The deposition precursor may be introduced to the process chamber 100 while maintaining a pressure of about 0.5 Torr to about 500 Torr, such as about 3 Torr to about 80 Torr, such as about 3 Torr to about 60 Torr, such as about 3 Torr to about 50 Torr, such as about 3 Torr to about 40 Torr, or such as about 3 Torr to about 5 Torr. The spacing between a substrate support and the chamber showerhead may be between about 100 mils and about 1500 mils, such as between about 200 mils and about 1000 mils.

The deposition precursor may be introduced to the process chamber 100 at a flow rate of about 10 milligrams per minute (mgm) to about 3000 mgm, such as about 100 mgm to ab out 2000 mgm, such as about 300 mgm to about 2000 mgm, such as about 1000 mgm to about 2000 mgm. Optionally, a carrier gas, e.g., helium, argon, krypton, neon, or a combination thereof, may additionally be provided to the process chamber. For example, the carrier gas can include helium, argon, or combinations thereof. The carrier gas may be flowed into the processing chamber at a constant flow rate of about 50 (standard cubic centimeters per minute) sccm to about 5,000 sccm, e.g., about 100 sccm to about 4,000 sccm, about 500 sccm to about 2,500 sccm, or about 1,000 sccm to about 1,500 sccm.

In some embodiments, which may be combined with other embodiments, a reactive gas, e.g., oxygen, may additionally be provided to the process chamber. The reactive gas includes oxygen containing compounds selected from the group of oxygen (O₂), nitrous oxide (N₂O), ozone (O₃), water (H₂O), carbon dioxide (CO₂), carbon monoxide (CO), and combinations thereof. The reactive gas may be flowed into the processing chamber at a constant flow rate of about 0 sccm to about 500 sccm, e.g., about 10 sccm to about 400 sccm, about 50 sccm to about 250 sccm, or about 100 sccm to about 150 sccm.

Operation 320 can include reacting the one or more deposition precursors, and optionally, the oxidizing gas and any inert gases, in the presence of RF power to deposit a low k film on a substrate in the chamber. The one or more deposition precursors implemented in the formation of the low k film include at least one compound that is represented by Formula (I) and/or Formula (II). For example, the one or more organosilane compounds may include a first compound and a second compound, wherein the first compound can be represented by either Formula (I) or Formula (II), and the second compound can be any organosilicon compound different from the first compound.

Optionally, RF power is applied to an electrode, such as the showerhead and/or substrate support, in order to provide plasma processing conditions in the chamber. The gas mixture is reacted in the chamber in the presence of RF power to deposit a low-k film comprising a silicon oxide layer that adheres strongly to the underlying substrate. For example, the deposition precursor may be introduced to the process chamber, in which a RF bias power may be applied to the substrate support at a frequency of about 10 Hz to about 15 MHz, e.g., about 100 Hz to about 100,000 Hz, about 1,000 Hz to about 100,000 Hz, about 10,000 Hz to about 100,000 Hz, or about 1 MHz to about 13 Mhz, may be applied to maintain a plasma in the processing volume. In some embodiments, the RF bias power may include a power of about 50 W to about 1000 W, e.g., about 100 W to about 900 W, about 200 W to about 800 W, about 300 W to about 700 W, about 400 W to about 600 W, or about 450 W to about 550 W.

A “pulse” or “dose” as used herein is intended to refer to a quantity of a source gas that is intermittently or noncontinuously introduced into the process chamber. The quantity of a particular compound within each pulse may vary over time, depending on the duration of the pulse. The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

In some embodiments, the resulting low-k films deposited onto the substrate have a thickness of greater than about 500 Å. In some embodiments, the resulting low k films deposited onto the substrate have a thickness of about 1000 Å to about 4000 Å.

At operation 330, a reactive precursor is introduced to the process chamber, e.g., process chamber 100. In some embodiments, the reactive precursor is an oxygen precursor, e.g., diatomic oxygen and/or ozone. Operation 330 can include the removal of the Si—OH bonds of the low-k film and the formation of the Si—O—Si bonds of the low-k film. The reactive precursor improves the dielectric constant, the breakdown voltage, the leakage current, and/or the hardness of the low-k film.

The reactive precursor is introduced to the process chamber at a flow rate of about 200 sccm to about 10,000 sccm, such as about 200 sccm to about 4000 sccm, such as about 300 sccm to about 3000 sccm, such as about 500 sccm to about 2000 sccm. The reactive precursor can be flowed into the process chamber for a period of time of about 0.5 min to about 10 min, e.g., about 0.5 min to about 9 min, about 1 min to about 8 min, about 2 min to about 7 min, about 3 min to about 6 min, or about 3 min to about 4 min. Other processing times and flow rates are also contemplated.

Optionally, a carrier gas, e.g., helium, argon, krypton, neon, or a combination thereof, may additionally be provided to the process chamber. For example, the carrier gas can include helium, argon, or combinations thereof. The carrier gas may be flowed into the processing chamber at a constant flow rate of about 0 sccm to about 30,000 sccm, e.g., about 1,000 sccm to about 25,000 sccm, about 5,000 sccm to about 20,000 sccm, or about 10,000 sccm to about 17,000 sccm.

The reactive precursor may be introduced to the process chamber while maintaining the temperature of the substrate and/or process chamber at about 5° C. to about 400° C., e.g., about 10° C. to about 350° C., about 20° C. to about 300° C., about 50° C. to about 300° C., or about 100° C. to about 300° C. Without being bound by theory, a reactive precursor that is introduced to the process chamber while maintaining a temperature of about 200° C. to about 400° C. can allow for a reduction of the dielectric constant, an increase of the breakdown voltage, and a reduction of the leakage current of the low-k film compared to the cleaned low-k film, while minimizing the reduction of hardness of the low-k film. In some embodiments, the reactive precursor may be introduced to the process chamber while maintaining a pressure of about 3 Torr to about 100 Torr, such as about 5 Torr to about 80 Torr, such as about 10 Torr to about 60 Torr, such as about 10 Torr to about 50 Torr, such as about 10 Torr to about 40 Torr, or such as about 10 Torr to about 15 Torr.

In some embodiments, the reactive precursor may be introduced to the process chamber, in which a RF bias power may be applied to the substrate support at a frequency of about 13 MHZ. For example, a RF bias power of less than about 100 W to about 1000 W, e.g., about 100 W to about 900 W, about 200 W to about 800 W, about 300 W to about 700 W, about 400 W to about 600 W, or about 450 W to about 550 W may be applied. Without being bound by theory, an RF bias of about 100 W to about 1000 W can allow for an increase of the dielectric constant, a decrease of the breakdown voltage, and an increase of the leakage current of the low-k film compared to the cleaned low-k film.

For example, the reactive precursor may be flowed into the chamber at a rate of about 200 sccm to about 10,000 sccm, such as about 200 sccm to about 4000 sccm, such as about 300 sccm to about 3000 sccm, such as about 500 sccm to about 2000 sccm. The substrate is maintained at a temperature of about 5° C. to about 400° C., e.g., about 10° C. to about 350° C., about 20° C. to about 300° C., about 50° C. to about 300° C., or about 100° C. to about 300° C. The substrate may be subjected to the plasma and the reactive precursor for about 0.5 min to about 10 min, e.g., about 0.5 min to about 9 min, about 1 min to about 8 min, about 2 min to about 7 min, about 3 min to about 6 min, or about 3 min to about 4 min.

At operation 340, the substrate is subjected to a post-treatment process. The post-treatment process can reduce the k value of the low-k film disposed over the substrate. Operation 340 may optionally include exposing the low-k film of the substrate to a recovery precursor, an ultraviolet (UV) light source, or a combination thereof. The recovery precursor can include an oxygen radical produced via ozone. In some embodiments which may be combined with other embodiments, operation 340 can be performed in the processing chamber 200 or in an alternative secondary processing chamber, e.g., a U.V. curing chamber, fluidly coupled to the processing chamber 100.

The low-k film is exposed to the UV light source while maintaining the temperature of the substrate and/or process chamber at about 75° C. to about 400° C., e.g., about 80° C. to about 350° C., about 90° C. to about 300° C., about 150° C. to about 300° C., or about 200° C. to about 300° C. The low-k film is exposed to the UV light source while maintaining the pressure of the process chamber at about 3 Torr to about 100 Torr, such as about 5 Torr to about 80 Torr, such as about 10 Torr to about 60 Torr, such as about 10 Torr to about 50 Torr, such as about 10 Torr to about 40 Torr, or such as about 10 Torr to about 15 Torr. The low-k film is treated with UV light for a period of time of about 0.5 min to about 10 min, e.g., about 0.5 min to about 9 min, about 1 min to about 8 min, about 2 min to about 7 min, about 3 min to about 6 min, or about 3 min to about 4 min.

A carrier gas, e.g., helium, argon, krypton, neon, or a combination thereof, may additionally be provided to the process chamber during the post-treatment process. For example, the carrier gas can include helium, argon, or combinations thereof. The carrier gas may be flowed into the processing chamber at a constant flow rate of about 0 sccm to about 30,000 sccm, e.g., about 1,000 sccm to about 25,000 sccm, about 5,000 sccm to about 20,000 sccm, or about 10,000 sccm to about 17,000 sccm.

Operation 340 includes the removal of the Si—OH bonds of the low-k film and the formation of the Si—O—Si bonds of the low-k film. Without being bound by theory, such chemical reactions may be performed via reaction schemes (1) and (2) shown below. Chemical reactions of schemes (1) and (2) illustrate the removal of the Si—OH bonds and the formation of the Si—CH₃ bonds when the low-k film is exposed to a recovery precursor.

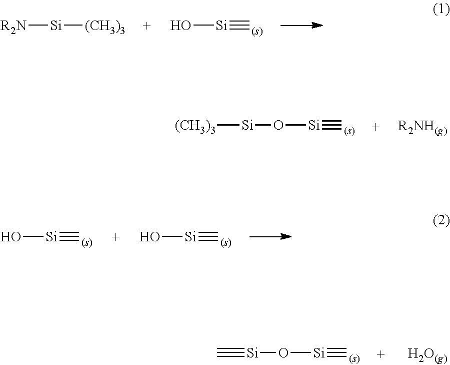

### EXAMPLES

### Example 1

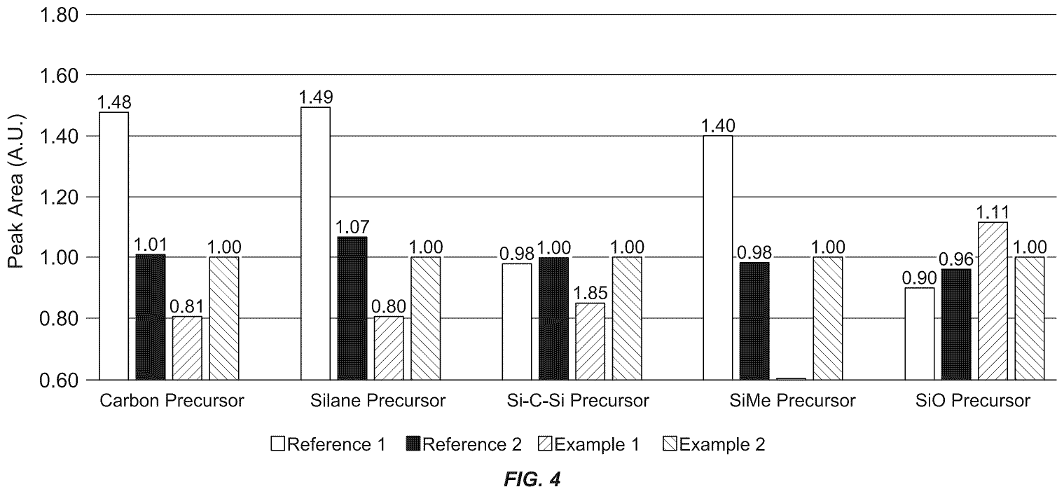

Samples were prepared in accordance to methods described herein, where a low-k film was deposited on a substrate, the low-k film was formed from a carbon precursor, a silane precursor, a silicon-carbon-silicon precursor, a methylsilicon precursor, and a silicon oxide precursor. The samples were analyzed with FTIR, in which the peak area was determined for an as-deposited low-k film (Reference 1), a low-k film post treated with UV light (Reference 2), a low-k film treated with a reactive gas, e.g., oxygen, and plasma followed by UV light (Example 1), and a low-k film treated with a reactive gas, e.g., oxygen, and heat followed by UV light (Example 1). Examples 1 and 2 were found to have a reduced FTIR peak area compared to References 1 and 2, as shown in FIG. 4.

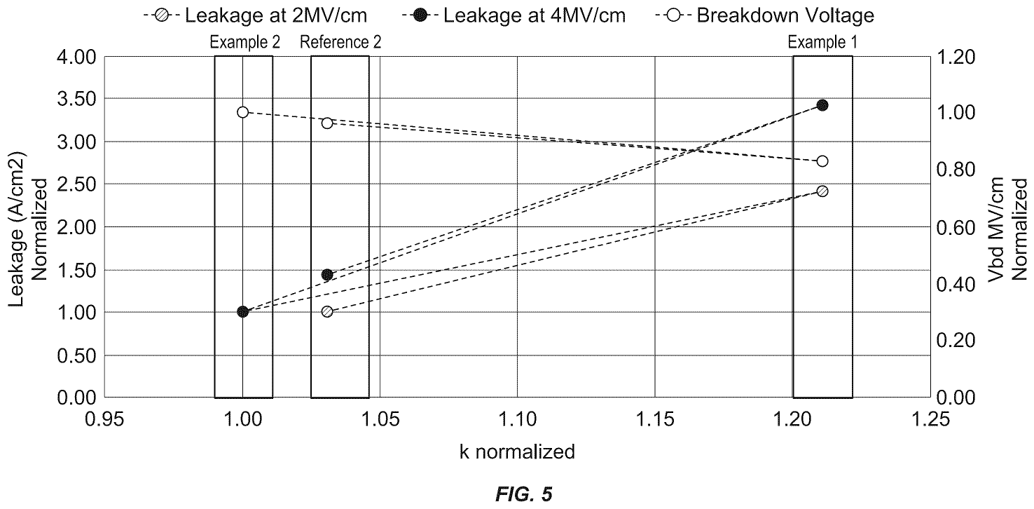

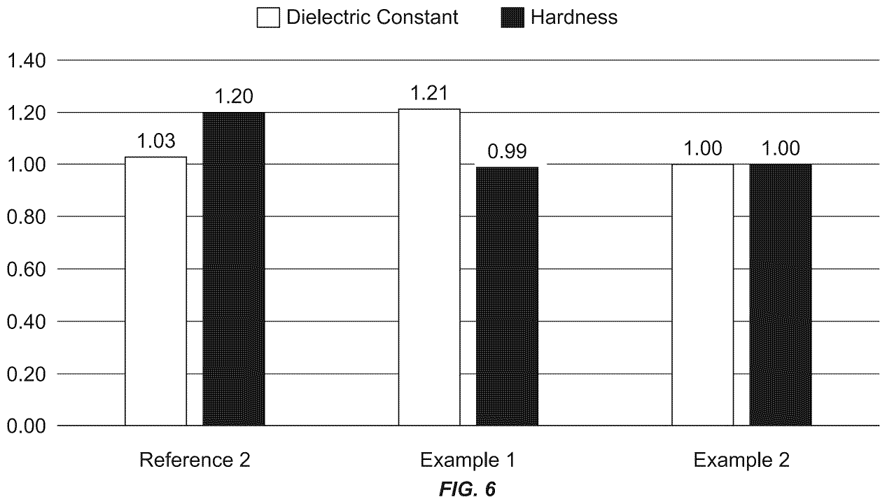

Example 1 had a higher leakage current at 4 MV/cm and at 2 MV/cm, as well as a lower breakdown voltage compared to Reference 2, as shown in FIG. 4. Example 2 had a lower leakage current at 4 MV/cm and at 2 MV/cm, as well as a higher breakdown voltage compared to Reference 2, as shown in FIG. 5. Additionally, Example 1 had a higher dielectric constant compared to Reference 2, while Example 2 had a lower dielectric constant compared to Reference 2. Each of Example 1 and Example 2 had a minimal reduction in hardness value after exposure to the reactive gas and plasma, as shown in FIG. 6.

Overall, the present disclosure provides methods to control dielectric constant properties, leakage properties, breakdown voltages, and hardness values of low-k films that were damaged during substrate processing procedures. Processes disclosed herein generally include a series of operations including exposing the substrate to one or more reactive precursors, e.g., an oxygenated precursor, in the presence of heat and/or plasma followed by exposure to a UV light source to allow for controllability of one or more of dielectric constant properties, leakage properties, breakdown voltages, and hardness values. Processes disclosed herein can reduce elevated k values of damaged low-k films, and also reduce leakage properties of such films, thereby enhancing device performance. Additionally, the processes of the present disclosure provide a balance between the reduction of low-k values, reduction of leakage properties, and increase of breakdown voltage properties, without sacrificing hardness values in low-k films, such that the resulting films have enhanced device performance compared to conventional low-k films.

While the foregoing is directed to embodiments of the present disclosure, other and further embodiments of the disclosure may be devised without departing from the basic scope thereof, and the scope thereof is determined by the claims that follow.

1. A method, comprising:
exposing a substrate in a processing chamber to a deposition precursor to form a first film, the first film having a first dielectric constant, a first leakage current, a first breakdown voltage, and a first hardness;
exposing the first film to a reactive precursor to form an second film, the second film having a second dielectric constant, a second leakage current, a second breakdown voltage, and a second hardness, wherein the reactive precursor comprises an oxygenated precursor; and
exposing the second film to a UV light source to form a third film, the third film having a third dielectric constant, a third leakage current, a third breakdown voltage, and a third hardness.

2. The method of claim 1, wherein the first dielectric constant, the second dielectric constant, and the third dielectric constant are different.

3. The method of claim 1, wherein the first leakage current, the second leakage current, and the third leakage current are different.

4. The method of claim 1, wherein the first breakdown voltage, the second breakdown voltage, and the third breakdown voltage are different.

5. The method of claim 1, wherein the first hardness, the second hardness, and the third hardness are different.

6. The method of claim 1, wherein the reactive precursor comprises an oxygenated precursor comprising diatomic oxygen or ozone.

7. The method of claim 1, further comprising producing a plasma in a process volume of the processing chamber and exposing the first film to the reactive precursor in the presence of the plasma.

8. The method of claim 7, wherein the plasma comprises a RF bias power of about 100 W to about 1000 W.

9. The method of claim 1, wherein exposing the first film to the reactive precursor to form the second film comprises:
introducing the reactive precursor at a flow rate of about 200 standard cubic centimeters per minute (sccm) to about 10,000 sccm;
introducing a carrier gas at a flow rate of about 0 sccm to about 30,000 sccm; and
maintaining a pressure of about 3 Torr to about 100 Torr.

10. The method of claim 9, wherein exposing the first film to the reactive precursor to form the second film comprises:
introducing the reactive precursor at a flow rate of about 500 sccm to about 2,000 sccm;
introducing the carrier gas at a flow rate of about 10,000 sccm to about 17,000 sccm; and
maintaining the pressure of about 10 Torr to about 15 Torr.

11. The method of claim 10, wherein the reactive precursor is introduced for a period of time of about 0.5 minutes (min) to about 10 min.

12. A method, comprising:
exposing a substrate in a processing chamber to a deposition precursor having a structure of Formula (I) to form a first film on the substrate, wherein Formula (I) is represented by: 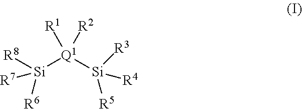
wherein:
Q¹ is a carbon atom or an oxygen atom; and
each of R¹, R², R³, R⁴, R⁵, R⁶, R⁷, and R⁸ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide;
exposing the first film to a reactive precursor comprising diatomic oxygen or ozone to form an second film; and
exposing the second film to a UV light source to form a third film.

13. The method of claim 12, wherein the first film comprises a first dielectric constant, the second film comprises a second dielectric constant, and the third film comprises a third dielectric constant, independently.

14. The method of claim 12, wherein the first film comprises a first leakage current, comprises a second leakage current, and the third film comprises a third leakage current, independently.

15. The method of claim 12, wherein the first film comprises a first breakdown voltage, the second film comprises a second breakdown voltage, and the third film comprises a third breakdown voltage, independently.

16. The method of claim 12, wherein the first film comprises a first hardness, the second film comprises a second hardness, and the third film comprises a third hardness, independently.

17. The method of claim 12, wherein exposing the first film to the reactive precursor comprises:
introducing the reactive precursor at a flow rate of about 500 standard cubic centimeters per minute (sccm) to about 2,000 sccm;
introducing a carrier gas at a flow rate of about 10,000 sccm to about 17,000 sccm; and
maintaining a pressure of about 10 Torr to about 15 Torr and a temperature of about 5° C. to about 400° C.

18. A method, comprising:
exposing a substrate in a processing chamber to a deposition precursor having a structure of Formula (I) to form a first film on the substrate, the first film having a first dielectric constant, a first leakage current, a first breakdown voltage, and a first hardness, wherein Formula (I) is represented by: 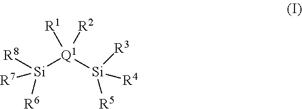
wherein:
Q¹ is a carbon atom or an oxygen atom; and
each of R¹, R², R³, R⁴, R⁵, R⁶, R⁷, and R⁸ is independently selected from a hydrogen atom, a substituted alkyl, an unsubstituted alkyl, a substituted alkoxy, an unsubstituted alkoxy, a substituted vinyl, an unsubstituted vinyl, a silane, a substituted amine, an unsubstituted amine, or a halide;
exposing the first film to a reactive precursor to form an second film, wherein exposing the first film comprises:
introducing the reactive precursor to the processing chamber at a flow rate of about 500 standard cubic centimeters per minute (sccm) to about 2,000 sccm;
introducing a carrier gas into the processing chamber at a flow rate of about 10,000 sccm to about 17,000 sccm; and
maintaining a pressure of about 10 Torr to about 15 Torr and a temperature of about 5° C. to about 400° C.; and
exposing the second film to a UV light source to form a third film.

19. The method of claim 18, wherein the reactive precursor comprises diatomic oxygen or ozone.

20. The method of claim 18, further comprising producing a plasma in a process volume of the processing chamber and exposing the first film to the reactive precursor in the presence of the plasma, the plasma comprising a RF bias power of about 100 W to about 1000 W.
